(19) United States
(12) Patent Application Publication
(10) Pub. No.: US 2025/0385736 A1
(43) Pub. Date: Dec. 18, 2025

(54) SYSTEM AND METHOD FOR THE TRANSMISSION OF RADIO SIGNALS ON OPTICAL FIBER

(71) Applicant: WISYCOM S.R.L., TOMBOLO (IT)

(72) Inventors: Enzo FRIGO, TOMBOLO (IT); Massimo POLO, TOMBOLO (IT)

(21) Appl. No.: 19/240,221

(22) Filed: Jun. 17, 2025

(30) Foreign Application Priority Data
Jun. 18, 2024 (IT) 102024000013855

(51) Int. Cl. H04B 10/2575

(52) U.S. Cl. CPC H04B 10/25759

(57) ABSTRACT

System for transmitting radio signals in fiber optic, comprising a receiving device, for receiving an input radio frequency electrical signal, first conversion means, for converting said input electrical signal into an optical signal, an optical fiber, for transmitting said optical signal at a distance, second conversion means, for converting said optical signal into a converted electrical signal and transmission means, for transmitting said converted electrical signal at the output of said system into an output electrical signal. The input electrical signal is sent to the input of a variable-gain amplifier driven by an electronic feedback device which receives as input the output signal from a wideband sensor or detector, for receiving as input the output signal from said variable-gain amplifier and being connected in series to an adapter circuit, the output of which is connected to said first conversion means. The adaptation circuit is a differential time constant circuit.

The present invention relates to a system for the transmission of radio signals on optical fiber, characterized by the presence of a variable-gain amplifier controlled by a feedback system with adjustable adaptation speed.

### SUMMARY OF THE INVENTION

The invention falls within the technical field of long-distance transmission of radio signals, typically emitted by a plurality of professional wireless microphones.

Such signals are collected at a physical location by an antenna (with or without an intermediate amplifier), which produces a signal over a cable (or another physical conductive medium, such as an interconnection within a chip or an electronic board), in the same frequency band as the original radio signals.

This radio signal is then typically converted into an optical signal, which is injected into an optical fiber and transmitted through the fiber over long distances.

At the other end of the optical fiber, even at distances on the order of kilometers, the signal is converted back from optical to electrical and processed by one or more remote receivers, which extract the information contained in the signal, typically but not exclusively, audio captured by the distant microphones.

These systems make it possible, for example, to serve a plurality of wireless microphones located across very large areas and far from the central radio signal processing unit.

### BACKGROUND OF THE INVENTION

Traditional systems for converting a radio frequency (RF) signal into an optical signal and then back from the optical signal to an RF signal present certain performance limitations.

In particular, these limitations concern two key performance parameters: the noise figure (NF) and the intermodulation products (IIP3, third-order products), which are primarily due to the nonlinear characteristics of the laser diode used in optical signal transmission.

To address these limitations, current technology provides amplifiers that boost the received signal and generate the signal used to drive the laser diode.

Since amplifiers generally exhibit significantly better performance than laser diodes, the performance constraints of such systems are ultimately determined by the limitations of the laser diodes themselves.

When designing such devices—intended to carry the RF signal received by an antenna to remote locations with negligible performance loss, the designer must take into account the signal levels present at the antenna and thus at the input of the optical link, and must design the laser diode driver stage to strike the best compromise between noise figure and intermodulation distortion immunity.

When optical links are used in environments where transmitting devices may approach the receiving antennas (for example, wearable or handheld wireless microphones used in radio audio systems for sporting events, concerts, TV and film productions, theater, etc.), where users are free to move within the coverage area, the transmitter may occasionally be very close to the receiving antenna, thereby generating a strong signal applied to the optical link input.

To avoid dangerous effects due to intermodulation or saturation/shutdown of the laser diode, which could result in the loss of some or all received signals—the designer is typically forced to keep the fixed gain of the input amplifier stage relatively low, thereby degrading the overall noise figure performance.

This degradation in the optical link's noise figure may undermine the performance of the radio receiving systems when the transmitters are physically far from the receiving antenna, ultimately compromising the effective range of the wireless systems.

The relevant prior art also comprises the patent documents WO2022/048751A1, CN212324104U and the document “Fast-Setting Two-Stage Automatic Gain Control for Multi-Service Fibre-Wireless Fronthaul Systems”.

In particular, prior art document WO2022/048751A1 describes the technical features which are presented in the preamble of claim 1.

### AIM OF THE INVENTION

An object of the present invention is to provide a system for the transmission of radio signals on optical fiber capable of overcoming the above-mentioned drawbacks and criticalities.

Another object of the present invention is to provide a system for the transmission of radio signals on optical fiber that is dynamically adaptable.

A further object of the present invention is to provide system for the transmission of radio signals on optical fiber with a reduced noise figure.

Another object of the invention is to provide a system for the transmission of radio signals on optical fiber with reduced intermodulation distortion.

Yet another object of the present invention is to provide a system for the transmission of radio signals on optical fiber controllable by a feedback mechanism.

An additional object of the present invention is to provide a system for the transmission of radio signals on optical fiber that performs optimally even over long distances.

Not least, an object of the invention is to provide system for the transmission of radio signals on optical fiber that is simple and cost-effective to manufacture, owing to the advantages achieved.

These and other objects are achieved by a system and a method for the transmission of radio signals over optical fiber as defined in the attached independent claims; additional technical features are set forth in the dependent claims.

### BRIEF DESCRIPTION OF THE DRAWINGS

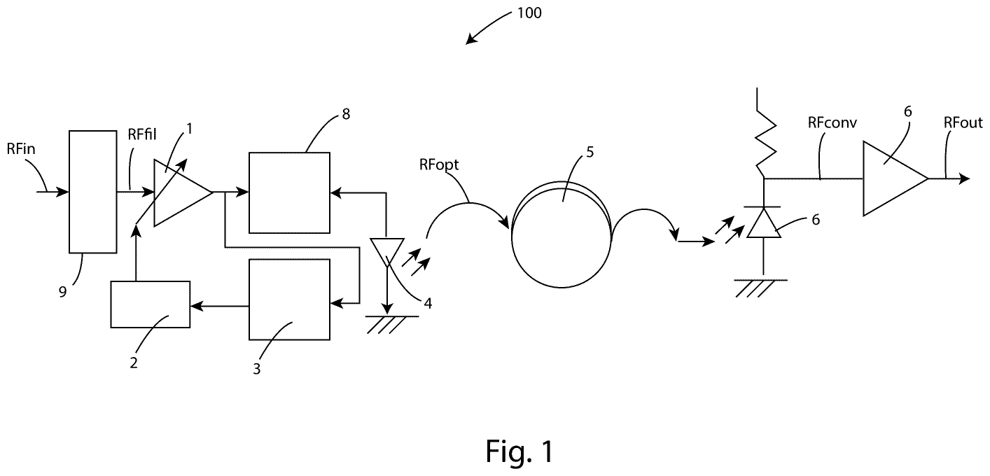

The present invention will now be described, purely by way of non-limiting example, according to some preferred embodiments thereof and with the aid of the attached FIG. 1, which shows a block diagram of the radio-over-fiber transmission system according to the invention.

### DETAILED DESCRIPTION OF THE PREFERRED EMBODIMENTS

With reference to the above-mentioned FIG. 1, the system for the transmission of radio signals on optical fiber, subject of the present invention, is generally indicated as 100 and, in the illustrated embodiment, is configured to receive an electrical radio frequency signal (RFin) and to convert it into an optical signal (RFopt), which is transmitted through a physical transmission medium, such as an optical fiber 5, and then converted back into an electrical signal (RFconv) by means of a conversion device such as a photodiode 6, and subsequently output from the system 100 through an amplifier 7 as an output signal (RFout).

In other words, the system 100 comprises the following step:
reception of the input electrical signal (RFin);
conversion of the signal RFin into an optical signal (RFopt) by means of a laser diode 4;
transmission of the optical signal RFopt through an optical medium, such as the optical fiber 5;
conversion of the optical signal RFopt back into an electrical signal (RFconv) by means of a photodiode 6;
transmission of the electrical signal RFconv at the output (RFout) of the system 100 by means of an amplifier 7.

More specifically, the input signal RFin, after being received through a reception device, such as an antenna, is filtered by a radio frequency filter 9.

Subsequently, the RFfil signal, thus filtered, is sent to the input of a variable-gain amplifier 1.

According to a preferred embodiment of the invention, the variable-gain amplifier 1 is driven by a suitable electronic feedback subsystem 2.

Advantageously, the electronic feedback subsystem 2 has at its input, in turn, the signal of a wide-band sensor or detector 3, which is connected to and has at its input the signal of an electrical-optical converter, such as a laser diode 4.

Always advantageously, the laser diode 4 is used to transmit the signal to its input in the physical transmission medium 5, which, in preferred embodiments, is an optical fiber.

The input signal to the laser diode 4 comes from a matching circuit 8, which, in turn, receives as input the output signal from the amplifier 1.

In practice, the idea behind the invention is to increase the gain of the input amplifier 1 when the overall signal power (given by the sum of the powers of all the signals received by the antenna) is low enough to allow this, without compromising the intermodulation robustness performance.

The measurement of the overall power of the signal (given by the sum of the received signals) is made at the driving point of the laser diode 4 and, if this power is equal to one or more orders of magnitude below the maximum possible power for the laser diode 4, an increase in gain of the input amplifier 1 is carried out, in order to decrease the noise figure of the system 100, since this is mainly linked to the noise of the laser diode 4.

In particular, the electronic feedback subsystem 2 is configured to dynamically adapt the input power to the laser diode 4 to make the system 100 work in the best conditions, with regard to performance figures such as the noise figure and the third-order intercept point.

Such dynamic adaptation is extremely fast in decreasing the gain of the input amplifier 1 when the input signal to the laser diode 4 increases in power and relatively slow in increasing the gain of the amplifier 1 when the input signal to the laser diode 4 decreases in power.

In particular, according to the invention, it is envisaged to increase the gain of the input amplifier 1 by an amount between 3 dB and 20 dB, starting from a nominal gain value, when the power of the input radio frequency electrical signal RFin is one or more orders of magnitude lower than the saturation power of the laser diode 4 and, subsequently, to decrease the aforementioned gain of the input amplifier 1, until it returns to the nominal gain value, when the power of the radio frequency electrical signal exceeds a predetermined threshold level of power applied to the laser diode 4.

The gain variation of the input amplifier 1 is achieved by using a feedback circuit (which advantageously includes the wide-band detector 3), which is a circuit with a time constant differentiated between “attack” and “release”; the time constant is in fact relatively slow (for example, between 0.1 and 5 seconds) when going towards an increase in gain of the amplifier 1, but fast (for example, between 0.1 and 50 milliseconds) when the antenna signal becomes strong again, so as to avoid saturation of the laser diode 4.

The variable-gain input amplifier 1 is driven by the electronic feedback subsystem 2, which, in turn, has as its input the signal at the output of the wideband detector 3; on the other hand, the wideband detector 3 is connected to the input of the matching circuit 8, whose output is connected to the transmission laser diode 4.

This circuit realization allows the system 100 to work automatically in the best dynamic conditions. From the description made, the characteristics of the system for the transmission of signals, object of the invention, are clear, as are the advantages.

It is clear, finally, that numerous other variations can be made to the system in question, without departing from the principles of novelty inherent in the inventive idea, just as it is clear that, in the practical implementation of the invention, the materials, shapes and dimensions of the illustrated details may be any according to the needs and the same may be replaced with other equivalent ones.

Where the characteristics and techniques mentioned in any claim are followed by reference signs, such reference signs have been included for the sole purpose of increasing the intelligibility of the claims and, consequently, such reference signs have no limiting effect on the interpretation of each element identified by way of example by such reference signs.

1. A system (100) for transmitting radio signals in fiber optic, comprising a receiving device, such as an antenna, capable of receiving an input radio frequency electrical signal (RFin), first conversion means (4), capable of converting said input radio frequency electrical signal (RFin) into an optical signal (RFopt), an optical fiber (5), suitable for transmitting said optical signal (RFopt) at a distance, second conversion means (6), suitable for converting said optical signal (RFopt) into a converted electrical signal (RFconv), and transmission means (7), such as an amplifier, suitable for transmitting said converted electrical signal (RFconv) at the output of said system (100) into an output electrical signal (RFout), characterized in that said input radio frequency electrical signal (RFin) is sent to the input of a variable-gain amplifier (1), wherein said variable-gain amplifier (1) is driven by an electronic feedback device (2) which receives as input the output signal from a wideband sensor or detector (3), said wideband sensor or detector (3) being capable of receiving as input the output signal from said variable-gain amplifier (1) and being connected in series to an adapter circuit (8), the output of which is connected to said first conversion means (4), characterized by the fact that said adaptation circuit (8) is a differential time constant circuit, said time constant being between 0.1 and 5 seconds when an increase in gain of said variable-gain amplifier (1) occurs and being between 0.1 and 50 milliseconds when the power of the input radio frequency electrical signal (RFin) is high enough.

2. The system (100) according to claim 1, characterized by the fact that an RF filter (9) is capable of filtering said input radio frequency electrical signal (RFin) and sending the filtered signal (RFfil) to said variable gain amplifier (1).

3. The system (100) according to claim 1, characterized by the fact that said first conversion means (4) include at least one laser diode.

4. The system (100) according to claim 1, characterized by the fact that said second conversion means (6) include at least one photodiode.

5. A process for transmitting radio signals in fiber optics in a transmission system (100) according to claim 1, characterized in that said electronic feedback device (2) is configured to dynamically adapt the input power to said at least one laser diode (4), via said variable gain amplifier (1) and via said wideband sensor or detector (3), by providing the following steps:
increasing the gain by an amount between 3 dB and 20 dB of said input amplifier (1), from a nominal gain value, when the power of said input radio frequency electrical signal (RFin) is one or more orders of magnitude less than the saturation power of said at least one laser diode (4), and
decrease said gain of said input amplifier (1), until it returns to said nominal gain value, when the power of said radio frequency electric signal exceeds a predetermined threshold level of power applied to said at least one laser diode (4).

6. The process according to claim 5, characterized by the fact that said predetermined threshold level of power applied to said at least one laser diode (4) is between −6 dB and −20 dB relative to a predetermined saturation threshold of said at least one laser diode (4).

7. A transmission procedure according to claim 5, characterized by the fact that said adaptation circuit (8) is a differential time constant circuit, said time constant being between 0.1 and 5 seconds when an increase in gain of said variable-gain amplifier (1) occurs and being between 0.1 and 50 milliseconds when the power of the input radio frequency electrical signal (RFin) is high enough.
